(19) United States
(12) Patent Application Publication
(10) Pub. No.: US 2010/0308475 A1
(43) Pub. Date: Dec. 9, 2010

(54) COMPOSITE OF AT LEAST TWO SEMICONDUCTOR SUBSTRATES AND A PRODUCTION METHOD

(76) Inventors: Achim Trautmann, Leonberg (DE); Ando Feyh, Tamm (DE)

Correspondence Address: KENYON & KENYON LLP, ONE BROADWAY, NEW YORK, NY, 10004, US

(21) Appl. No.: 12/733,861

(22) PCT Filed: Sep. 2, 2008
(86) PCT No.: PCT/EP2008/061548

§ 371 Date: Jul. 1, 2010

(30) Foreign Application Priority Data
Oct. 9, 2007 (DE) 10 2007 048 332.7

(51) Int. Cl. H01L 23/488; H01L 21/768

(52) U.S. Cl. 257/783; 438/612; 257/E23.023; 257/E21.59

(57) ABSTRACT

A composite, including a first semiconductor substrate that is secured by soldering material to at least one second semiconductor substrate, a eutectic being formed between the soldering material and the second semiconductor substrate and/or at least one layer possibly provided on the semiconductor substrate. It is provided that the eutectic is formed between the soldering material and a microstructure, which is formed in the region of contact with the soldering material on the second semiconductor substrate and/or the layer. Also described is a production method.

### FIELD OF THE INVENTION

The present invention relates to a composite of at least two semiconductor substrates, as well as a method for producing a composite.

### BACKGROUND INFORMATION

In semiconductor technology, for example, for producing MEMS (Micro-Electro-Mechanical Systems), it is necessary to firmly connect two semiconductor substrates to each other, for example, in order to encapsulate electronics and/or micromechanics mounted on one of the semiconductor substrates. The use of eutectic bonding connections to connect two semiconductor substrates is known. A thin eutectic is formed between a soldering material and one of the semiconductor substrates, and it is responsible for the firm connection. A disadvantage of the known method and the composites of at least two semiconductor substrates produced using it is that the bonding strength of the connection is not sufficient for some applications. In addition, it is a disadvantage that the soldering material has to be deposited relatively thickly, which means that the entire composite is built up relatively high.

### SUMMARY OF THE INVENTION

An objective of the exemplary embodiments and/or exemplary methods of the present invention is thus to provide a composite of at least two semiconductor substrates, which is optimized with regard to a high bonding strength. Furthermore, the objective is to provide a corresponding production method.

With respect to the composite of at least two semiconductor substrates, this objective is achieved by the features described herein and with respect to the production method by the features described herein. Advantageous further refinements of the exemplary embodiments and/or exemplary methods of the present invention are provided in the dependent claims. In order to avoid repetitions, features disclosed in terms of the device alone shall also count as disclosed and be claimable in terms of the method. Likewise, features disclosed in terms of the method alone shall count as disclosed and be claimable in terms of the device.

The exemplary embodiments and/or exemplary methods of the present invention has recognized that an enlargement of the eutectic layer, that is, of the eutectic, in particular the enlargement of the thickness extension of the eutectic, results in an increase in the firmness of the connection between soldering material and semiconductor substrate. In order to enlarge the thickness extension of the eutectic, in particular relative to the total thickness of the soldering material, the exemplary embodiments and/or exemplary methods of the present invention provides the semiconductor substrate with a microstructure, at least in sections in the region of contact between the semiconductor substrate and the soldering material.

If the soldering material does not come into direct contact with the semiconductor substrate, in particular because an additional layer is provided between the semiconductor substrate and the soldering material, which additional layer is deposited on the semiconductor substrate, it is within the scope of the present invention to provide this layer with a microstructure. It is essential for the soldering material to interact with a microstructure. In the sense of the exemplary embodiments and/or exemplary methods of the present invention, microstructure is understood as a structure having structure widths and/or heights in the range of a few micrometers to several 10 μm, in particular having structure widths and/or heights between approximately 5 μm and approximately 50 μm. Providing a microstructure on the semiconductor substrate and/or possibly providing an additional layer on or in this layer, enlarges the thickness extension of the eutectic relative to a composite from the related art, in particular in the edge region of the microstructure and/or in recesses of the microstructure. This may be attributed, for example, to the capillary forces acting on the eutectic, which is liquid due to heating, in the region of the microstructure, which forces cause the eutectic to form in a thickened manner, in particular on lateral sides of the microstructure.

Both constituents of the soldering material and constituents (atoms) of the semiconductor substrate, and/or if a layer is provided on the semiconductor substrate, constituents (atoms) of this layer material, are found in the developing eutectic layer. The developing eutectic layer is characterized by the fact that its above-mentioned constituents are in such a proportion to each other that at a specific liquidus temperature they become liquid as a whole. This temperature must be produced in order to form the eutectic layer or the eutectic when producing the composite. Due to the capillary forces acting as a result of the microstructure, a particularly thick eutectic layer and thus a high-strength connection between the soldering material and the semiconductor substrate is obtained.

On the whole, the deposit thickness of the soldering material may be significantly reduced by providing the microstructure. Experiments have shown that the invention allows for firm connections to be produced even when the deposit thickness of the soldering material is reduced by a factor of 5 in comparison with the related art, with the additional advantage that, on the whole, the composite does not build up as high. Enlarging the eutectic layer not only increases the bonding strength of the composite, it also increases the electric conductivity, which means that the soldering material may be used not only to connect the two semiconductor substrates, but also for the electric contacting of active and/or passive electronic components of the semiconductor substrates.

The microstructure may be produced in the semiconductor substrate with the aid of a reshaping method and/or by erosive etching methods. The layer that is optionally provided on the semiconductor substrate may be microstructured as well. It is also conceivable to deposit such a layer as already microstructured, for example, to print it, or to vapor deposit it, for example, using a CVD method.

In addition to providing the previously explained liquidus temperature, it may be necessary, depending on the materials used, to implement a suitable contact pressure on the semiconductor substrate during the production of the composite.

Providing a eutectic connection as described above makes it possible to replace currently used sealing-glass bond frames. It is within the scope of the exemplary embodiments and/or exemplary methods of the present invention to provide the microstructure not only on one semiconductor substrate or a layer that is optionally deposited on it, but on both semiconductor substrates or layers possibly situated on the them, so that the soldering material interacts on two opposite sides with one microstructure, respectively. It is also conceivable to provide a microstructure only on one semiconductor substrate or on a layer that is optionally provided on it, and to provide an adhesive layer on the other semiconductor substrate, which “holds” the semiconductor material without the formation of a eutectic.

Particularly advantageous is a specific embodiment in which the soldering material is deposited in such a manner that it projects beyond the microstructure on at least one side, which may be on all sides, i.e., essentially crosswise to the thickness extension, so that in the circumferential edge region of the microstructure, in particular on the (lateral) shoulders of the microstructure, a thickened eutectic layer is formed.

A previously described composite of at least two semiconductor substrates may be distinguished by the fact that the eutectic layer is thicker in the circumferential edge region of the microstructure, in particular on (lateral) shoulders of the microstructure and/or in at least one recess or on recess shoulders in the microstructure, than it is in at least one elevated, which may be planar region of the microstructure. The thickness extension of the eutectic may be greater than 1 micrometer, at least regionally, and particularly may be greater than 5 micrometers.

A specific embodiment is particularly advantageous in which the soldering material not (only) has the job of connecting the at least two semiconductor substrates to each other, but also in which the soldering material is used to produce an electric connection between two passive or active electric components, such as circuit traces or transistors, disposed on different semiconductor substrates. In particular, due to the reduced deposit thickness of the soldering material and the, in comparison to the total thickness of the soldering material, thick eutectic layer, an optimum conductivity is achieved.

A specific embodiment is particularly preferred in which an adhesive layer is disposed on one of the additional semiconductor substrates, as mentioned at the outset, in order to “hold” the soldering material. This adhesive layer may be deposited by vapor deposit, for example. The adhesive layer may be formed in such a manner that the liquid soldering material does not wet it or wets it only slightly. It is within the scope of the development to provide this adhesive layer with a microstructure before depositing the soldering material, or to deposit the adhesive layer in an already microstructured manner. As an alternative to providing the adhesive layer, it is possible for the soldering material to contact the semiconductor substrate directly, in particular in order to form a eutectic bond with the latter. In this case, it is advantageous to provide the semiconductor substrate, or a layer possibly provided between the semiconductor substrate and the soldering material, with a microstructure, or to develop it as a microstructure.

In addition to or as an alternative to producing an electrically conductive connection between the at least two semiconductor substrates, it is conceivable to dispose the soldering material or the formed eutectic layer in the form of a bond frame, in particular a ring-shaped bond frame, which may enclose an electronic circuit or a micromechanical component. On the basis of such a disposition of the soldering material, the electronic circuit may be capped and hermetically encapsulated by affixing the additional semiconductor substrate.

In a development of the exemplary embodiments and/or exemplary methods of the present invention, it is advantageously provided that the width extension (crosswise to the thickness extension) of the microstructure, which may be of the bond frame, has a maximum width of 200 micrometers, which may be of only approximately 100 micrometers, and particularly may be of only approximately 50 micrometers or less, in order to be able to utilize the largest surface area possible of at least one semiconductor substrate for installing active and/or passive electric components.

In a development of the exemplary embodiments and/or exemplary methods of the present invention, it is advantageously provided that a material is provided on at least one of the semiconductor substrates, which may be on both semiconductor substrates, and particularly may be in a ring-shaped manner around the soldering material or the formed eutectic layer, which may be vapor-deposited, which does not allow for, or possibly only allows a slight, wetting with liquid eutectic, so that an unchecked lateral overflow of the eutectic over the microstructure is minimized, which may be completely prevented.

The exemplary embodiments and/or exemplary methods of the present invention also provides a method for producing a previously described composite. The core idea of the method is to provide at least one of the semiconductor substrates with a microstructure before depositing the soldering material or bringing it into contact with the soldering material, and/or to provide a layer possibly deposited on the semiconductor substrate with a microstructure or to deposit it as already microstructured, in order to thus achieve the formation of a eutectic layer having a greater thickness extension in comparison with the related art, at least regionally, in particular through the effect of capillary forces.

A specific embodiment of the method is particularly preferred, in which the soldering material is secured on an additional semiconductor substrate, which may be on an adhesive layer provided on the latter, before it is brought into contact with the previously described microstructure. The soldering material may be heated after or even already during the joining of the at least two semiconductor substrates, by inserting the not yet fixed composite into a soldering furnace, for example. The composite is possibly also additionally subjected to pressure (contact pressure). The temperature of the soldering material, at least in the region of contact with the microstructure, must be sufficiently high to ensure the formation of a eutectic layer between the microstructure material and the soldering material.

Additional advantages, features and details of the exemplary embodiments and/or exemplary methods of the present invention derive from the following description of preferred exemplary embodiments as well as from the figures.

### BRIEF DESCRIPTION OF THE DRAWINGS

FIG. 1a shows a production step for producing a composite according to the related art shown in FIG. 1b.

FIG. 1b shows a composite, as known from the related art.

FIG. 2 shows a production step in the production of a composite designed according to the concept of the present invention.

FIG. 3 shows an additional method step in the production of the composite, the semiconductor substrates that are to be connected to each other being joined.

FIG. 4 shows a detail enlargement from FIG. 3.

FIG. 5 shows an enlarged illustration of a first exemplary embodiment of a composite designed according to the concept of the present invention.

FIG. 6 shows a specific embodiment of a composite that is an alternative to the composite according to FIG. 5, a layer preventing an overflow of liquid eutectic being deposited around a microstructure.

### DETAILED DESCRIPTION

Identical components and components having the same function are labeled by the same reference symbols in the figures.

The related art is illustrated in FIG. 1a and FIG. 1b. A first, flat semiconductor substrate 1 may be seen, in particular a wafer on which an adhesive layer 2 has been vapor-deposited. Soldering material 3, which is used to connect first semiconductor substrate 1 to a second semiconductor substrate 4 disposed in the drawing plane below it, bonds to this planar adhesive layer.

FIG. 1b illustrates a completely developed, known composite 5, including first semiconductor substrate 1 and second semiconductor substrate 4. It can be seen that between planar second semiconductor substrate 4 and soldering material 3, a thin eutectic 6 has been formed, which is responsible for the connection of second semiconductor substrate 4.

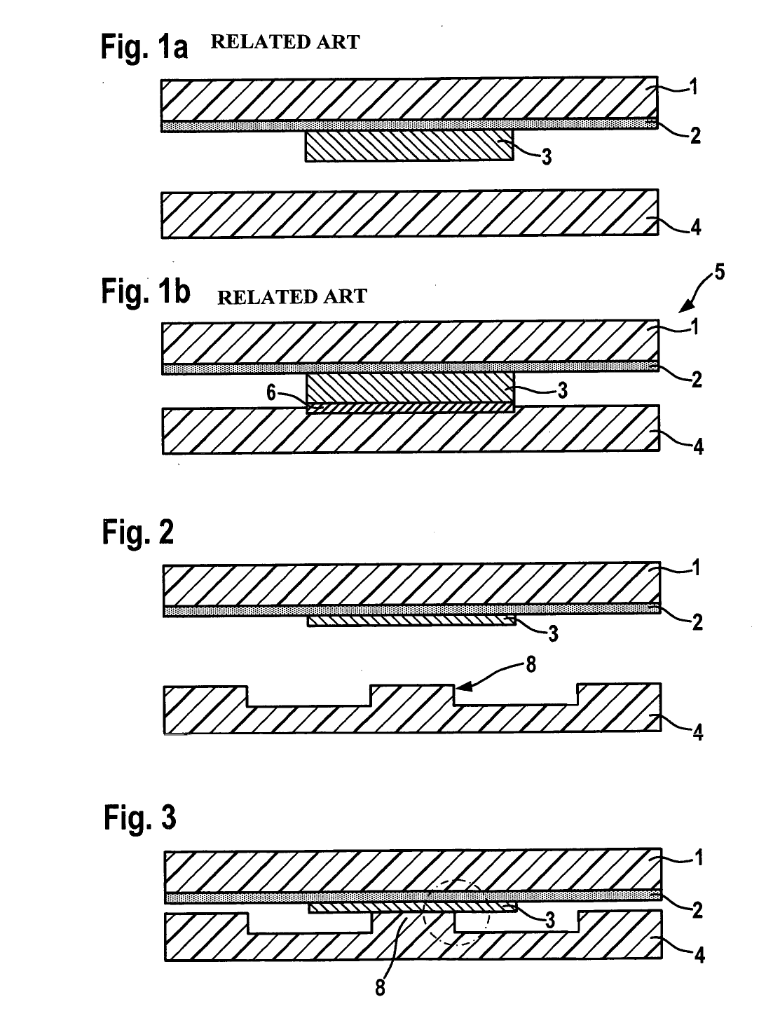

FIG. 2 illustrates a method step in the production of a composite 5 shown in sections in FIGS. 5 and 6. The upper half of the drawing in FIG. 2 shows a first semiconductor substrate 1, onto which an adhesive layer 2 was vapor-deposited in a previous step. Soldering material 3 was deposited on this adhesive layer 2. In the exemplary embodiment shown, first semiconductor substrate 1 is made up of silicon. Adhesive layer 2 is designed in such a manner that it does not allow for a wetting with melted soldering material or at most allows for a slight wetting with melted soldering material. It can be seen in FIG. 2 that the thickness extension of soldering material 3 is significantly lower than in the exemplary embodiments according to the related art. The thickness extension amounts to approximately ⅕ of the thickness extension in a known composite 5 (compare FIG. 1a and FIG. 1b).

First semiconductor substrate 1 provided with soldering material 3 is to be firmly connected to a second semiconductor substrate 4 disposed in the drawing plane below it. Second semiconductor substrate 4 is formed from silicon in the exemplary embodiment shown. Soldering material 3 is made up of gold (essentially). Alternatively, first semiconductor material 1 may be formed from silicon or germanium. Second semiconductor substrate 4 may be alternatively formed from silicon oxide or germanium, for example. Instead of using gold as a soldering material, it is possible to use aluminum, AlCu, or AlSiCu. The adhesive layer on first semiconductor substrate 1 is formed from chrome in the exemplary embodiment shown.

As may be seen from the bottom of FIG. 2, second semiconductor substrate 4 is not formed in a planar manner, but rather features a microstructure 8 in a subsequent region of contact 7 with soldering material 3, which is visible in FIG. 3. It may be seen that soldering material 3 projects beyond microstructure 8 on the sides, i.e., crosswise to its thickness extension. In the exemplary embodiment shown, microstructure 8 is designed as a simple structural block. Additionally or alternatively, microstructure 8 may be made up of a plurality of elevations and trenches. The height of the elevations or the depth of the trenches may be at least 2 μm, which may be at most 40 μm. Likewise, the width of individual structure sections of the microstructure may be at least 1 μm and which may be at most 40 μm. The total width of microstructure 8 in the illustrated exemplary embodiment amounts to between 20 and 200 μm.

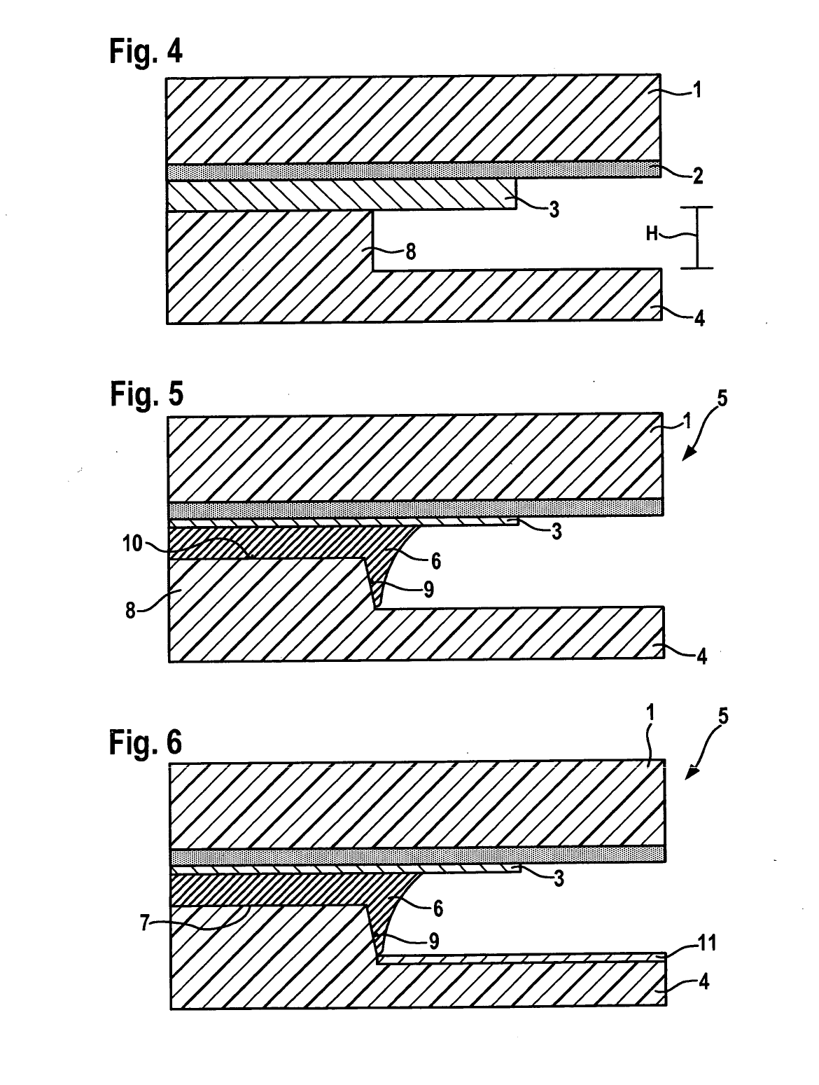

FIG. 4 illustrates an enlarged detail from FIG. 3. In it, height H (thickness extension) of microstructure 8, in this exemplary embodiment 10 μm, is labeled. It is particularly clear in FIG. 4 that thin soldering material 3 projects laterally beyond microstructure 8, in the transverse direction. In the exemplary embodiments shown, microstructure 8 is produced directly in second semiconductor substrate 4 by using a reshaping method or an erosive method. Additionally or alternatively, it is conceivable to deposit microstructure 8 or a microstructure section through a depositing method, through vapor depositing or printing, for example. If an additional thin layer (not shown) is deposited on second semiconductor material 4 in such a manner that it is located at least in sections between second semiconductor material 4 and soldering material 3, it is advantageous to pattern this layer or to deposit it as already patterned.

After first semiconductor substrate 1 has been joined with second semiconductor substrate 4, as shown in FIGS. 3 and 4, the composite system obtained in this manner may be transferred into a soldering furnace, in which a temperature above a liquidus temperature of a eutectic 6 illustrated in FIGS. 5 and 6 prevails. Where necessary, a contact pressure may additionally be applied to semiconductor substrates 1, 4, which may be in the direction of joining. During the solder process, atoms diffuse from second semiconductor substrate 4 into soldering material 3, and vice versa, which forms illustrated eutectic 6. The active capillary forces “attract” forming eutectic toward an outer shoulder region 9 (circumferential edge region) of microstructure 8, which means that eutectic 6 in shoulder region 9 is relatively thick in comparison with an elevated region 10 of microstructure 8. In the exemplary embodiment shown, the thickness of eutectic 6 in shoulder region 9 is more than 20 μm.

FIG. 6 shows an alternative exemplary embodiment of a completed composite 5. The only difference from the exemplary embodiment according to FIG. 5 is that microstructure 8 is surrounded circumferentially by a material 11 that may not be wetted by eutectic 6, in order to prevent an uncontrolled overflow of liquid eutectic 6, which forms during the solder process, out of region of contact 7.

In a modification of the illustrated exemplary embodiments, adhesive layer 2 or an additional or alternative layer or first semiconductor substrate 1 may also be provided with a microstructure before soldering material 3 is deposited.

In the illustrated exemplary embodiments (FIGS. 5 and 6), eutectic 6 is made up of gold and silicon constituents. Depending on the material combination of soldering material 3 and semiconductor substrate material of second semiconductor substrate 4 or possibly a layer deposited on it, eutectic 6 may be formed from the constituents AlCu/Si, AlSiCu/Si, Al/Si, Au/Ge, Al/Ge oder AlCu/Ge, AlSiCu/Ge, for example. Additional material pairings may also be implemented.

1-12. (canceled)

13. A composite, comprising:
a first semiconductor substrate; and
at least one second semiconductor substrate, wherein the first semiconductor substrate is secured by a soldering material to the at least one second semiconductor substrate, wherein a eutectic is formed between the soldering material and at least one of (i) the at least one second semiconductor substrate and (ii) at least one layer provided on the at least one second semiconductor substrate, and wherein the eutectic is formed between the soldering material and a microstructure, which is formed in a region of contact with the soldering material in at least one of (i) the at least one second semiconductor substrate and (ii) in the at least one layer.

14. The composite of claim 13, wherein the soldering material projects laterally beyond the microstructure.

15. The composite of claim 13, wherein the eutectic is thicker at least one of (i) in an edge region of the microstructure and (ii) in at least one recess within the microstructure than in at least one elevated region of the microstructure.

16. The composite of claim 13, wherein the soldering material forms an electric contact.

17. The composite of claim 13, wherein an adhesive layer is disposed between the soldering material and the first semiconductor substrate.

18. The composite of claim 13, wherein at least one of the first semiconductor substrate and an adhesive layer provided on the first semiconductor substrate is microstructured.

19. The composite of claim 13, wherein the soldering material is disposed in the form of a bond frame.

20. The composite of claim 13, wherein the microstructure has a maximum total width of 200 μm.

21. The composite of claim 13, wherein the microstructure is surrounded on its sides, at least in sections by a material preventing a lateral overflow of liquid eutectic.

22. The composite of claim 13, wherein the microstructure is one of configured as a one-part microblock and is made up of a plurality of trenches and elevations.

23. A method for producing a composite between a first semiconductor substrate and a second semiconductor substrate, the method comprising:
providing a first semiconductor substrate;
providing a second semiconductor substrate; and
depositing soldering material at least one of on the second semiconductor substrate and on at least one layer provided on the second semiconductor substrate, wherein a eutectic is formed between the soldering material and at least one of the second semiconductor substrate and the layer, wherein at least one of the second semiconductor substrate and the layer in a region of contact with the soldering material is microstructured before at least one of the soldering material is deposited and the layer is deposited as already microstructured before the soldering material is deposited.

24. The method of claim 23, wherein the soldering material is deposited on at least one of the first semiconductor substrate and an adhesive layer provided on it before being deposited at least one of on the second semiconductor substrate and on the layer.

25. The composite of claim 13, wherein the soldering material projects laterally beyond the microstructure, on all sides.

26. The composite of claim 13, wherein the microstructure has a maximum total width of 100 μm.

27. The composite of claim 13, wherein the microstructure is surrounded on its sides, at least in sections, completely, by a material preventing a lateral overflow of liquid eutectic.

28. The composite of claim 13, wherein the microstructure is one of configured as a one-part microblock and is made up of a plurality of trenches and elevations, and wherein at least one of widths and heights of the structure are configured in a size range between approximately 1 μm and approximately 10 μm.

29. The composite of claim 13, wherein the microstructure has a maximum total width of 50 μm.
